(19) United States
(12) Patent Application Publication
(10) Pub. No.: US 2012/0031425 A1
(43) Pub. Date: Feb. 9, 2012

(54) MODULES AND PROCESSES FOR METAL PARTICLES REMOVAL

(75) Inventors: Ofer Kadar, Sunnyvale, CA (US); Ofer Amir, Half Moon Bay, CA (US); Babu Chinnasamy, Bangalore (IN)

(73) Assignee: APPLIED MATERIALS, INC., Santa Clara, CA (US)

(21) Appl. No.: 13/206,368

(22) Filed: Aug. 9, 2011

Related U.S. Application Data
(60) Provisional application No. 61/372,053, filed on Aug. 9, 2010.

(51) Int. Cl. B08B 1/04; B08B 7/00; B08B 1/02

(52) U.S. Cl. 134/1; 15/77; 15/88.3

(57) ABSTRACT

Embodiments of the present invention provide an apparatus and methods for processing solar cell devices. In one embodiment, a method removing particles from edge regions of the solar cell device by a cleaning module with a constant loading applied onto a back surface of the solar cell device, wherein the cleaning modules has two or more roller-type brushes disposed at opposed sides of a rotation table located before and/or after a quality assurance stage configured to measure and correct defects in the solar cell device, and transferring the solar cell device into an edge deletion station in which an electromagnetic radiation energy is used to remove materials from a top surface of the solar cell device. The roller-type brushes include non-abrasive bristles configured to remove unwanted material from the periphery region of the solar cell device prior to transferring into the edge delete station.

### CROSS-REFERENCE TO RELATED APPLICATIONS

This application claims benefit of U.S. provisional patent application Ser. No. 61/372,053, filed Aug. 9, 2010, which is herein incorporated by reference.

### BACKGROUND OF THE INVENTION

1. Field of the Invention

Embodiments of the present invention generally relate to apparatus and processes for performing thin-film edge cleaning on a solar cell device in a solar cell production line.

2. Description of the Related Art

Photovoltaic (PV) devices or solar cells are devices which convert sunlight into direct current (DC) electrical power. Typically, a thin film solar cell includes active regions, or photoelectric conversion units, and a transparent conductive oxide (TCO) film disposed as a front electrode on the bottom of the solar cell in contact with a front glass substrate and/or as a back electrode on the top of the solar cell. The photoelectric conversion unit may include a p-type silicon layer, an n-type silicon layer, and an intrinsic type (i-type) silicon layer sandwiched between the p-type and n-type silicon layers. Several types of silicon films such as microcrystalline silicon film (pc-Si), amorphous silicon film (a-Si), polycrystalline silicon film (poly-Si), and the like may be utilized to form the p-type, n-type, and/or i-type layers of the photoelectric conversion unit. The backside electrode may contain one or more conductive layers. A metal back contact layer, such as silver, is then deposited over the backside electrode by a physical vapor deposition (PVD) process.

Seaming and edge deletion are standard operations necessary for the fabrication of solar cells. This process provides electrical separation of the active cells in a solar module and a good surface for attaching a sealing layer to seal off the edge of the solar cell from the outside environment, by removing the conductive layers along the edge of the solar cell module with a high-energy laser beam. However, it has been reported that silver, and other unwanted particles which originat from the formation of the metal back contact layer, are also deposited or wrapped around the edges of the glass during the PVD deposition of the silver layer. Once this material isexposed to powerful illumination such as a laser beam used in a laser edge delete tool at later stage, or possibly after many hours of exposure to sunlight, the material oxidizes and becomes apparent to the human eye, causing color variation in the resulting solar cell module and/or a long-term product reliability risk.

Therefore, a need exists for a particle removal tool that is capable of effectively removing unwanted metal particles from the periphery region of solar cell substrates prior to exposing the substrate to powerful illumination used in the laser edge delete tool at later stage.

### SUMMARY OF THE INVENTION

Embodiments of the present invention provide an apparatus and methods for cleaning edge regions of a solar cell device. In one embodiment, a method for processing a solar cell device includes removing particles from edge regions of the solar cell device with a cleaning module with a constant loading applied onto a back surface of the solar cell device, wherein the cleaning module has two or more roller-type brushes disposed at opposed sides of a rotation table located before and/or after a quality assurance stage configured to measure and correct defects in the solar cell device, and transferring the solar cell device into an edge deletion station in which an electromagnetic radiation energy is used to remove materials from a top surface of the solar cell device. The two or more roller-type brushes may include non-abrasive bristles made of a material selected from the group consisting of Nylon 4-6, Nylon 6, Nylon 6-6, Nylon 6-9, Nylon 6-10, Nylon 12, and Nylon 6-12.

In another embodiment, a method for processing a solar cell device includes advancing the solar cell device onto a first rotation table equipped with a first set of edge cleaning brushes to remove particles from a first two opposing edges of the solar cell device, transferring the solar cell device into a quality assurance station configured to measure and correct defects in the solar cell device, advancing the solar cell device onto a second rotation table equipped with a second set of edge cleaning brush to remove particles from a second two opposing edges of the solar cell device, and transferring the solar cell device into an edge deletion station in which an electromagnetic radiation energy is used to remove materials from a top surface of the solar cell device.

In yet another embodiment, the present invention provides an apparatus for processing a solar cell device including a quality assurance station configured to measure and correct defects in a solar cell device, a conveyor configured to transport the solar cell device onto a first rotation table equipped with a first edge cleaning module, the first rotation table being located immediately upstream of the quality assurance station, and the first edge cleaning module comprising a first set of roller-type brushes disposed on opposing sides of the first rotation table, the first set of roller-type brushes being configured to be in contact with a back surface of the solar cell device with a constant upward loading, and a motor configured to rotate the first set of roller-type brushes, and an edge deletion station configured to remove material from a top surface of the solar cell device at opposing edge regions of the solar cell device using an electromagnetic radiation energy. The apparatus may further include a second rotation table located immediately downstream of the quality assurance station and configured to receive the solar cell device on the conveyor from the quality assurance station, the second rotation table being equipped with a second edge cleaning module, the second edge cleaning module comprising a second set of roller-type brushes disposed on opposing sides of the second rotation table, the second set of roller-type brushes being configured in contact with a back surface of the solar cell device with a constant upward loading, and a motor configured to couple to and rotate the second set of roller-type brushes.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a process sequence for forming a solar cell device using a solar cell production line according to one embodiment of the present invention.

FIG. 2 illustrates a plan view of a solar cell production line according to one embodiment of the present invention.

FIG. 3 illustrates a side cross-sectional view of a thin film solar cell device.

FIG. 4 illustrates a schematic, top view of an exemplary arrangement of first and second sets of edge cleaning modules, rotation tables, and a quality assurance module.

FIG. 5 illustrates a partial, schematic, top view of a first rotation table having a first set of edge cleaning module according to one embodiment of the present invention.

FIG. 6 illustrates a partial, schematic, isometric view of the first set of edge cleaning module according to one embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

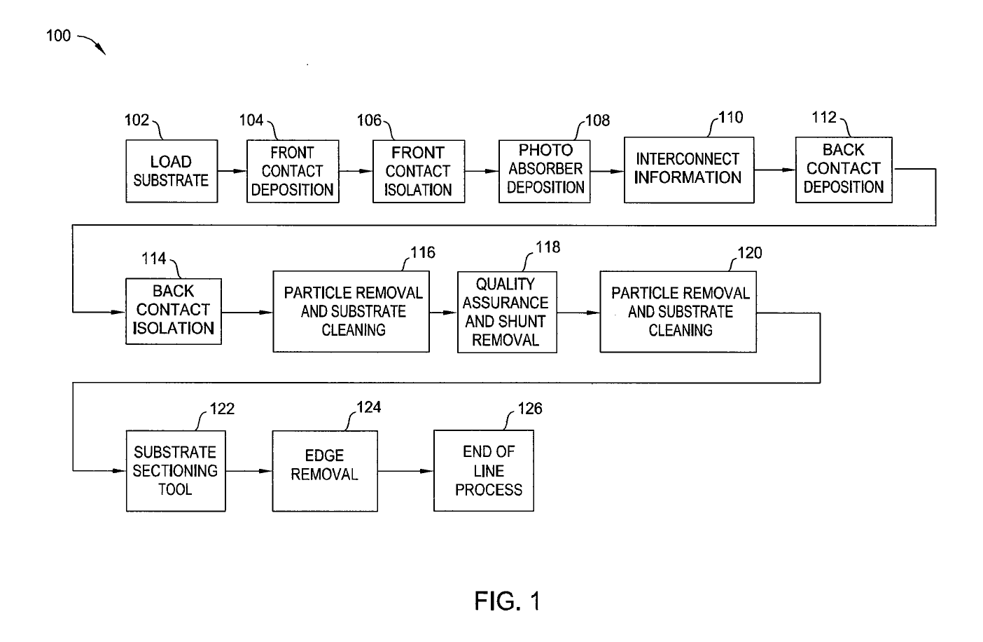

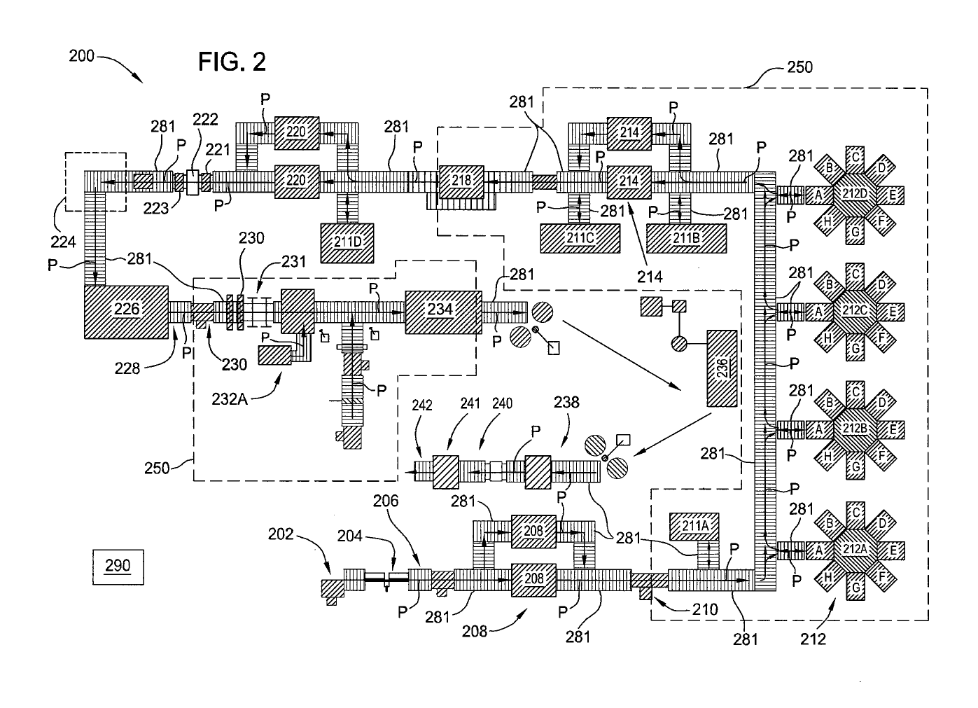

The present invention generally relates to an edge cleaning module positioned within an automated solar cell fabrication line. The automated solar cell fabrication line, as will be discussed below in conjunction with FIGS. 1 and 2, is generally an arrangement of automated processing modules and automation equipment used to form solar cell devices. The inventive edge cleaning module generally includes one or more sets of cleaning modules, each being equipped with roller-type nylon brushes, mounted on opposing sides of a rotation table located upstream and/or downstream of a quality assurance module to remove unwanted metal materials from the periphery region of the solar cell device prior to transferring into the edge delete tool in the automated solar cell fabrication line.

FIG. 1 illustrates one embodiment of a process sequence 100 that contains a plurality of steps (i.e., steps 102-126) that are each used to form a solar cell device using a novel solar cell production line 200 described herein. The configuration, number of processing steps, and order of the processing steps in the process sequence 100 is not intended to be limiting to the scope of the invention described herein. FIG. 2 is a plan view of one embodiment of the production line 200, which is intended to illustrate some of the typical processing modules and process flows through the system and other related aspects of the system design, and is thus not intended to be limiting to the scope of the invention described herein.

A system controller 290 may be used to control one or more components found in the solar cell production line 200. The system controller 290 facilitates the control and automation of the overall solar cell production line 200 and typically includes a central processing unit (CPU) (not shown), memory (not shown), and support circuits (or I/O) (not shown). A program (or computer instructions) readable by the system controller 290 determines which tasks are performable on a substrate. Preferably, the program is software readable by the system controller 290 that includes code to perform tasks relating to monitoring, moving, supporting, and/or positioning of a substrate along with various process recipe tasks and various chamber process recipe steps performed in the solar cell production line 200.

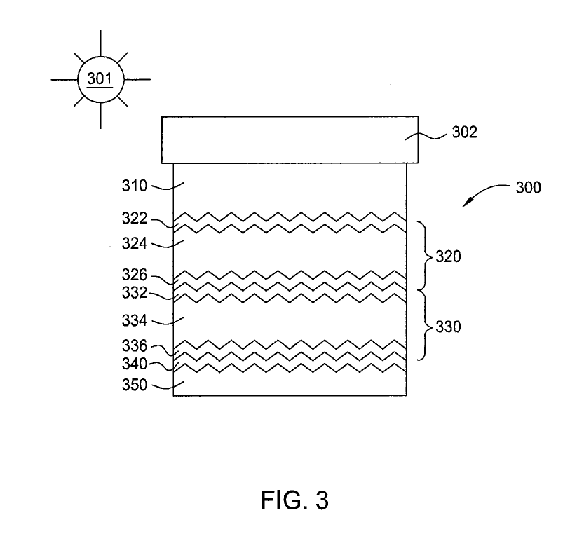

An Example of a solar cell that can be formed and tested using the process sequences illustrated in FIG. 1 and the components illustrated in the solar cell production line 200 is illustrated in FIG. 3. FIG. 3 is a simplified schematic diagram of a multi-junction amorphous or micro-crystalline silicon solar cell 300 oriented toward the light or solar radiation 301 and can be formed in the system described below.

The solar cell 300 comprises a substrate 302, such as a glass substrate, polymer substrate, metal substrate, or other suitable substrate, with thin films formed thereover. The solar cell 300 may further comprise a first transparent conducting oxide (TCO) layer 310 formed over the substrate 302, a first p-i-n junction 320 formed over the first TCO layer 310, a second p-i-n junction 330 formed over the first p-i-n junction 320, a second TCO layer 340 formed over the second p-i-n junction 330, and a back contact layer 350 formed over the second TCO layer 340. To improve light absorption by enhancing light trapping, the substrate and/or one or more of the thin films formed thereover may be optionally textured by wet, plasma, ion, and/or mechanical processes. For example, in the embodiment shown in FIG. 3, the first TCO layer 310 is textured, and the subsequent thin films deposited thereover generally follow the topography of the surface below it.

Multiple silicon based layers may be used in a silicon-containing film stack to provide one or more, e.g., multiple, junctions to improve light conversion efficiency. In one embodiment, the first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. The second p-i-n junction 330 may comprise a p-type microcrystalline silicon layer 332, an intrinsic type microcrystalline silicon layer 334 formed over the p-type microcrystalline silicon layer 332, and an n-type amorphous silicon layer 336 formed over the intrinsic type microcrystalline silicon layer 334. Suitable examples of the silicon-containing film stack are disclosed in U.S. application Ser. No. 11/624,677, filed Jan. 18, 2007 by Choi et al, titled “Multi-Junctions Solar Cells and Methods and Apparatus for Forming the Same”, and are herein incorporated by reference.

A back contact layer 350 is deposited over the silicon-containing film layer (i.e., the second p-i-n junction 330), or optionally over a second transparent conductive oxide (TCO) layer as shown, which may be similar to the first TCO layer 310 and serve as a back electrode. The metal back contact layer 350 may include, but is not limited to, a material selected from the group consisting of Al, Ag, Ti, Cr, Au, Cu, Pt, Ni, Mo, alloys thereof, or combinations thereof. While not discussed here, other films or materials may be provided over the back contact layer 350 to complete the solar cell. The solar cells may be interconnected to form modules, which in turn can be connected to form arrays for a higher performance.

### General Solar Cell Formation Process Sequence

Referring back to FIGS. 1 and 2, the process sequence 100 generally starts at step 102 in which a substrate 302 as discussed above is loaded into the loading module 202 found in the solar cell production line 200. It may be advantageous to receive “raw” substrates 302 that have a transparent conducting oxide (TCO) layer (e.g., first TCO layer 310) already deposited on a surface of the substrate 302 before it is received into the system in step 102. If a conductive layer, such as TCO layer, is not deposited on the surface of the “raw” substrates then a front contact deposition step (step 104), which is discussed below, needs to be performed on a surface of the substrate 302. In one embodiment of the solar cell production line 200, one or more regions in the production line may be positioned in a clean room environment to reduce or prevent contamination from affecting the solar cell device yield and useable lifetime. In one embodiment, a class 10,000 clean room space 250 is placed around the modules used to perform steps 102-126.

The substrate is then inserted into a front end substrate seaming module 204 that is used to prepare the edges of the substrates 302 to reduce the likelihood of damage, such as chipping or particle generation from occurring during the subsequent processes. Next the substrates 302 are transported to a c leaning module 206 where a substrate cleaning step may be performed on the substrates 302 to remove any contaminants found on the surface of the substrates 302.

Prior to performing step 106 the substrates 302 are transported to a front end processing module (not illustrated in FIG. 2) in which a front contact formation process, or step 104, is performed on a surface of the substrate 302. In one embodiment, step 104 includes one or more PVD steps that are used to form the front contact region on a surface of the substrate 302. The front contact region contains a transparent conducting oxide (TCO) layer that may contain metal element selected from a group consisting of zinc (Zn), aluminum (Al), indium (In), and tin (Sn). The front end processing module may be an ATON™ PVD 5.7 tool available from Applied Materials in Santa Clara, Calif. in which one or more processing steps are performed to deposit the front contact region.

Next the substrate 302 is transported to the scribe module 208 in which step 106, or an interconnect formation process, is performed on the substrate 302 to electrically isolate different regions of the substrate 302 surface from each other. In step 106, material is removed from the substrate 302 surface by use of a material removal step, such as a laser ablation process. The substrate 302 is then transported to a cleaning module 210 in which a pre-deposition substrate cleaning step is performed on the substrate to remove any contaminants found on the surface of the substrate after performing the cell isolation step. A substrate cool down step may be performed in one or more accumulators 211A prior to entering the processing module 212A-212D.

Next, the substrate 302 is transported to the processing module 212A-212D in which step 108, which comprises one or more photoabsorber deposition steps, is performed on the substrate 302. Step 108 generally includes a series of sub-processing steps that may be used to form one or more p-i-n junctions as the tandem junction solar cell 300 illustrated in FIG. 3.

Next, the substrate 302 is transported to the scribe module 214 in which step 110, or an interconnect formation step, is performed on the substrate 302 to electrically isolate various regions of the substrate 302 surface from each other. In step 110, material is removed from the substrate 302 surface by use of a material removal step, such as a laser ablation process. An Nd:vanadate (Nd:YVO₄) laser source may be used to ablate material from the substrate surface to form lines (linear voids in the ablated film layer) that electrically isolate one solar cell from the next. A substrate cool down step may be performed in one or more accumulators 211B, 211C before and after the interconnect formation step.

Next, the substrate 302 is transported to the processing module 218 in which one or more substrate back contact formation steps, or step 112, are performed on the substrate 302. Step 118 generally includes one or more PVD steps that are used to form the back contact layer 350 on the surface of the substrate 302. In one embodiment, the one or more PVD or CVD steps are used to form a back contact region that contains a metal layer selected from a group consisting of zinc (Zn), tin (Sn), aluminum (Al), copper (Cu), silver (Ag), nickel (Ni), vanadium (V), molybdenum (Mo), and conductive carbon. In one example, a zinc oxide (ZnO) or nickel vanadium alloy (NiV) is used to form at least a portion of the back contact layer 350. A substrate cool down step may be performed in one or more accumulators 211D after the back contact formation step.

Next, the substrate 302 is transported to the scribe module 220 in which step 114, or a back contact isolation step, is performed on the substrate 302 to electrically isolate the plurality of solar cells contained on the substrate surface from each other. In step 114, material is removed from the substrate surface by use of a material removal step, such as the laser ablation process similar to step 106 as discussed previously.

Next, the substrate 302 is transported through an edge cleaning module (e.g., a first set of edge cleaning module 221) in which step 116, or a particle removal cleaning step, is performed on the substrate 302 to remove any metal particles or contaminants from the edges of the substrate 302. As will be discussed below in the section entitled, “Edge Cleaning Module and Processes”, the edge cleaning module 221 may include one or more sets of cleaning heads that are mounted on opposing side edges of a first rotation table, upstream of a quality assurance module 222, to clean the first two opposing sides of the substrate 302.

Next, the substrate 302 is transported to the quality assurance module 222 in which step 118, or quality assurance and/or shunt removal steps, are performed on the substrate 302 to assure that the devices formed on the substrate surface meet a desired quality standard and in some cases correct defects in the formed device.

Next, the substrate 302 is transported through an edge cleaning module (e.g., a second set of edge cleaning module 223) in which step 120, or a particle removal cleaning step, is again performed on the substrate 302 to remove any metal particles or contaminants from the edges of the substrate 302. As will be discussed below in the section entitled, “Edge Cleaning Module and Processes”, the edge cleaning module 223 may include one or more sets of cleaning heads mounted on opposing sides of a second rotation table downstream of a quality assurance module 222 to clean the remaining two opposing side edges of the substrate 302 that has been rotated about 90 degree in the first rotation table. While the first and second rotation tables are described to be located upstream and downstream of the quality assurance module 222, respectively, it is contemplated that the first and second rotation tables may be both located upstream or downstream of the quality assurance module 222 to clean the edges of the substrate 302, depending upon the process regime.

Next, the substrate 302 is optionally transported to the substrate sectioning module 224 in which a substrate sectioning step 122 is used to cut the substrate 302 into a plurality of smaller substrates 302 to form a plurality of smaller solar cell devices.

Referring back to FIGS. 1 and 2, the substrate 302 is next transported to the seamer/edge deletion module 226 in which a substrate surface and edge preparation step 124 is used to remove a portion of the film stack from a top surface of the substrate at opposing edge regions of the substrate 302. The substrate 302 is positioned in the seamer/edge deletion module 226 to remove a portion of the film stack along the edge of the substrate 302 to reduce the likelihood of damage, such as clipping or particle generation, from occurring during subsequent processing. Next the substrate 302 is transported to a pre-screen module 228 where an optional pre-screen step is performed on the substrate 302 to assure that the devices formed on the substrate surface meet a desired quality standard. Thereafter, the substrate 302 is transported to a cleaning module 230 where a pre-lamination substrate cleaning step may be performed to remove any contaminants found on the surface of the substrates 302.

The device substrate 303 is then transferred using one or more of the automation devices 281 to one of the substrate cutting module modules 224, edge deletion module 226, cleaning module 230, bonding wire attach module 231, glass lay-up module 232, and bonding modules 234

At step 126, end of the line processes are performed on the substrate 302. End of the line processes generally include final wire attaching (performed in the bonding wire attach module 231), packaging and/or bonding (performed in the bonding modules 234), and device test and analysis processes. After the support structure, wiring structures, or framing structures are formed on the substrate, the substrate 302 is transported to one of the junction box attachment modules 238, testing modules 240, support structure attachment module 241, and to an unload module 242 to remove the formed solar cells from the solar cell production line 200 and the solar cell fabrication process is completed.

It is contemplated that other process sequences associated with the solar cell device fabrication may also be adapted to use the particle removal and substrate cleaning process of the present invention as will be descried below.

### Edge Cleaning Module and Processes

As briefly discussed above, it has been found that the cleanliness of the surface in the edge region of the substrate is important to long-term product reliability. To assure the cleanliness of the surface in the edge region of the substrate, a set of edge cleaning module may be mounted on a rotation table located upstream and/or downstream of the quality assurance module 222 to remove silver or unwanted metal particles from all four edges of the substrate 302 prior to transferring into the edge delete tool. It is understood that the “edge” of the substrate as used herein refers to periphery portions of the substrate 302, which typically has a width between about 10 mm and about 25 mm measured from the edge of substrate 302.

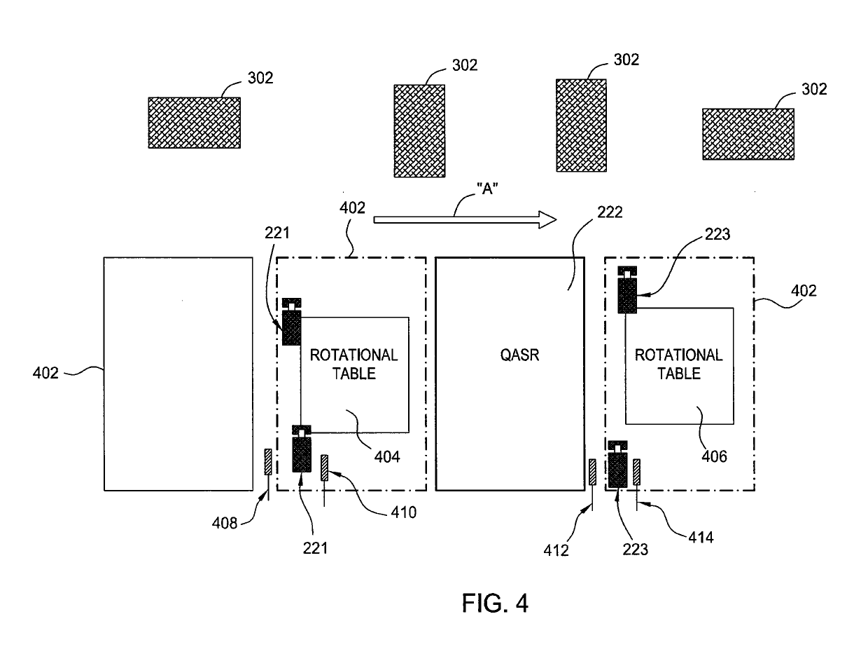

FIG. 4 depicts a schematic, top view of an exemplary arrangement of first and second sets of edge cleaning modules 221, 223, the rotation tables 404, 406, and the quality assurance module 222 that may be incorporated into the production line 200 (FIG. 2). Typically, a conveyor 402, such as the automation device 281, is used to transport the substrate 302, following arrow “A”, through a first set of edge cleaning modules 221 mounted at two opposing sides of the first rotation table 404, to the quality assurance module 222, and then through a second set of edge cleaning modules 223 mounted at two opposing sides of the second rotation table 406. In order to remove unwanted materials from all four edges of the substrate 302, the substrate 302 may be rotated after the long sides (in cases where a rectangular substrate is used) have been cleaned by the first set of edge cleaning modules 221. The short sides of the substrate are then cleaned by the second set of edge cleaning modules 223 and the substrate is rotated again prior to transferring into the edge delete tool. An exemplary rotation of the substrate 302 during different stages of the edge cleaning process is conceptually shown in FIG. 4.

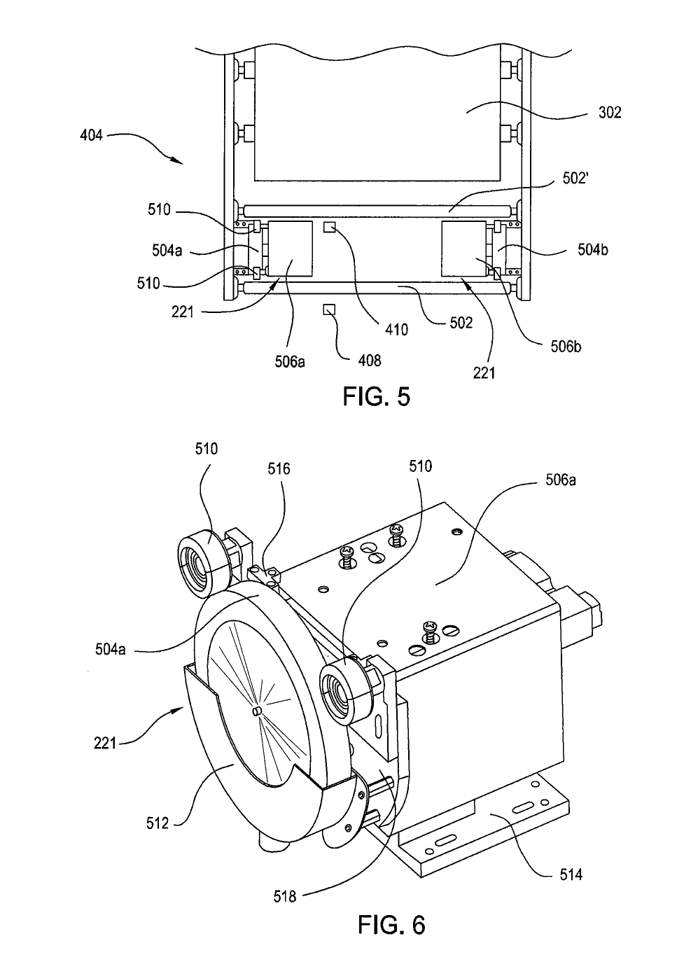

A first start-sensor 408 may be arranged adjacent to the first set of edge cleaning module 221 at the first rotation table 404 to detect entry of incoming substrates and activate the first set of edge cleaning module 221. The first start-sensor 408 may be a proximity sensor or an optical sensor emitting an IR beam to detect the edge of the substrate 302. In cases where a rectangular substrate having a width of about 2.2 m and a length of about 2.6 m is used, the 2.2 m side can be the leading edge being sensed by the first start-sensor 408. The first start-sensor 408 then sends signals to one or more actuators (not shown), such as a motor, which rotates polishing wheels 504a, 504b (FIG. 5) of the first set of edge cleaning module 221 and contacts the substrate to remove unwanted materials from the edges (i.e., the 2200 mm side) of the substrate by use of mechanical friction.

FIG. 5 illustrates a partial, schematic, top view of a first rotation table 404 having a first set of cleaning units that form the first edge cleaning module according to one embodiment of the present invention. The first set of edge cleaning module 221 generally includes a pair of polishing wheels 504a or 504b disposed on opposing sides of the first rotation table 404. The polishing wheels 504a, 504b may be arranged offset or parallel to each other and disposed between two adjacent conveying rollers 502, 502′ of the first rotation table 404 upon which the substrate 302 is traveling. While not discussed here, it is contemplated that the space between two opposing edge cleaning modules and/or the first two conveying rollers may vary depending upon the size of the substrate or process scheme.

During the edge cleaning process, the substrate 302 is placed on and transported by the conveyor 402 through the first and second sets of edge cleaning modules 221, 223 sequentially. A plurality of conveying rollers 502, 502′ are controlled to rotate and cause the conveyor 402 to move in the direction indicated by the arrow “A” (FIG. 4). The polishing wheel 504a is disposed beneath the substrate 302 and configured to be urged against the back surface of the substrate 302 as the substrate 302 advances to remove any attached particles from the edge surfaces of the first two opposed sides of the substrate 302. The polishing wheel 504a may be rotated in a direction opposite to the direction of the substrate 302 movement. In such a case, the polishing wheel 504a may be constructed in a way that it is also movable along the moving substrate 302, thereby reducing the overall space taken by the rotation tables 404, 406. Alternatively, the polishing wheel 504a may be rotated in the same direction as the substrate movement. The polishing wheel 504a may be coupled to an actuator that rotates the polishing wheel 504a to place the bristles in contact with the edges of the substrate 302. The actuator may move the polishing wheel 504a in a X-Y direction so that the polishing wheel 504a may be moved along the periphery region of the substrate 302 while the polishing wheel 504a is being in contact with the substrate 302 to sweep unwanted particles from the edges of the substrate 302.

The polishing wheel 504a, 504b may be a roller-type brush having a plurality of bristles utilized to sweep particles or residue on the substrate 302. The wheel brush may be made of a non-abrasive or medium abrasive material such as nylon fibers. The material and width of the wheel may vary depending upon the material and/or area of the substrate to be cleaned, as will be discussed later.

Referring back to FIG. 4, to prevent the polishing wheel from constantly running, a first stop-sensor 410 may be arranged and configured to temporarily stop the first set of brushes of the edge cleaning module 221 once the presence of the trailing edge of the substrate 302 is no longer detected by the first stop-sensor 410. The substrate 302 is then rotated about 90 degree by the first rotation table 404 before entering the quality assurance module 222, as conceptually shown in FIG. 4. After the quality assurance and/or shunt removal steps are done, the substrate 302 is transported by the conveyor 402 to the second rotation table 406 where the second set of brushes of the edge cleaning module 223 are located to clean the remaining two opposed sides of the substrate 302. Except for a wider spacing between the two brushes of the second edge cleaning module 223 that is required to process 2600 mm sides of the substrate 302 (if a rectangular substrate is used), the second edge cleaning module 223 has the polishing ability substantially similar to that of the first set of edge cleaning module 221. Similar to the first start-sensor 408 and the first stop-sensor 410, a second start-sensor 412 and a second stop-sensor 414 may be arranged upstream and downstream of the second edge cleaning module 223, respectively, to control the activation of the second edge cleaning module 223. Alternatively, a single sensor (not shown) may be used to control the operation of the first and second edge cleaning modules 221, 223 based upon the movement of the substrate 302 theretrhrough.

Before exiting the second rotation table 406, the remaining two opposed sides of the substrate 302 are brush processed to be substantially free of unwanted metal particles. The substrate 302 is then rotated about 90 degrees by the second rotation table 406, and the substrate 302 exits the second rotation table 406 following arrow “A” for further processing as previously described in FIG. 1. Thus, the substrate has the same orientation upon leaving the clean modules at it had when it entered the cleaning modules. It is contemplated that the first and second sets of edge cleaning modules 221, 223 may be disposed at any desired location, and thus at locations other than being disposed immediately upstream and downstream of the quality assurance module 222 as shown. For example, the first and second sets of edge cleaning modules 221, 223 may be placed between the scribe module 220 and the substrate sectioning module 224, or before the seamer/edge deletion module 226, depending upon the process regime.

While not shown, it is contemplated that multiple sets of edge cleaning modules, such as first and second sets of edge cleaning modules 221, 223, may be arranged at the first and/or second rotation table 404, 406 to enhance edge surface cleaning. A desired number of edge cleaning modules may be disposed in a series fashion on opposing sides of the first and/or second rotation tables 404, 406. In cases where two sets of edge cleaning modules are arranged in a rotation table, the polishing wheel of the first set of edge cleaning module may remove the coated material layers from the back surface edges of the substrate 302, and the second set of edge cleaning module may remove any remaining materials or particles from the back surface edges of the substrate 302. Thus, a good surface cleanliness is provided to a predetermined edge region along each side of the substrate 302, which is needed for later edge delete, lamination or packaging.

FIG. 6 is a partial, schematic, isometric view of the first set of edge cleaning module 221 according to one embodiment of the present invention. While only one polishing wheel 504a and motor mount 506a are shown for illustration purpose, it is understood that each of the first or second set of edge cleaning module 221, 223 may be provided with a pair of polishing wheels 504a, 504b and arranged parallel to each other and positioned to be aligned with the opposed sides of the first or second rotation table 404, 406. The description as discussed herein applies to both first and second sets of edge cleaning modules 221, 223.

As shown in FIG. 6, the first set of edge cleaning module 221 generally includes a motor mount 506a, a motor (not shown) disposed in the motor mount 506a, two substrate followers 510, a polishing wheel 504a, and a dust collector 512. The motor mount 506a is typically mounted to a cross support 514 to be arranged between two adjacent conveying rollers 502, 502′ (FIG. 5). The motor mount 506a may include a vertical adjustment member (not shown) and a horizontal adjustment member (not shown) that may comprise dual adjustment mechanisms, such as coarse and fine threaded adjustment screws. The vertical adjustment member and the horizontal adjustment member may be used for setting initial alignment of the polishing wheel 504a for edge cleaning of the substrate. In addition, the vertical adjustment member may be advanced at regular use intervals or in light of the decreasing diameter of the polishing wheel 504a due to polishing operation, thereby compensating for the radial loss of bristle material and assuring that a consistent polishing process occurs at one or more intervals during edge cleaning of the substrate.

A constant pressure member 516 may be included in the first set of edge cleaning module 221 to ensure there is a constant pre-loading between the polishing wheel 504a and the substrate (not shown). The force with which the polishing wheel 504a is pressed against the surface of the substrate 302 is controlled by the load on the constant pressure member 516 and/or the motor which rotates the polishing wheel 504a. The constant pressure member 516 may include a mechanical, pneumatic, or hydraulic system of springs and dampers for ensuring the polishing wheel 504a provides a constant upward pressure onto the substrate 302 during the edge cleaning process regardless of thickness variation of the substrate 302. The application of a constant upward pressure onto the substrate irrespective of the actual substrate thickness is advantageous since it automatically compensates for wear in the polishing wheel 504a.

To enhance a constant pre-loading between the polishing wheel 504a and the substrate, two or more substrate followers 510 may be optionally provided adjacent to the polishing wheel 504a to assist in adjusting the height of the polishing wheel 504a and transportation of the substrate 302 thereon. The upper end of the substrate followers 510 is substantially level with the upper end of the polishing wheel 504a. The substrate followers 510 may be directly or indirectly mounted, along with the polishing wheel 504a, to a preloading plate 518 which is vertically movable relative to the motor mount 506a. In operation, the substrate 302 travels on the substrate followers 510, which in turn cause the preloading plate 518 to move up and down following the thickness variation of the silver deposited on the backside of the substrate 302. As the polishing wheel 504a is coupled to the preloading plate 518, the movement of the preloading plate 518 will guide the polishing wheel 504a to move accordingly, thereby providing a predetermined, constant pre-loading between the polishing wheel 504a and the substrate 302. Therefore, the first set of edge cleaning module 221 may remove the same amount of material from the back surface of the substrate 302 regardless of thickness variation of the silver deposited on the backside of the substrate 302.

In one embodiment, as the substrate moves on the conveying rollers 502, 502′ (the conveyor 402 not shown in FIG. 5), the leading edge of the substrate 302 may be sensed via a first start-sensor 408 disposed at a desired location proximity to the first set of edge cleaning module 221. The lateral position of the polishing wheel 504a may be adjusted automatically by the system controller 290 such that the movable polishing wheel 504a is in position to remove the desired amount of material from the edges of the substrate 302. The system controller 290 receives signals from the first start-sensor 408 and sends signals to an actuator such as the motor (not shown, disposed within the motor mount 506a, 506b) to rotate the polishing wheel 504a. Alternatively, the polishing wheel 504a may be located manually such that the first or second set of edge cleaning module 221, 223 may be used to remove material from the edges of the substrate 302. If desired, the polishing wheel 504a, the substrate followers 510, and the motor mount 506a may be separately controlled to ensure proper alignment during the edge cleaning process. The loading, material, and/or wheel velocity of the polishing wheels which affects the amount of material removed will be discussed later.

Depending upon the material chosen for the polishing wheel 504a, a cooling or polishing fluid may be introduced onto at least a portion of the polishing wheel 504a which then flows around the outer circumference of the polishing wheel 504a to enhance the edge cleaning results. The polishing wheel 504a may deliver coolant or abrasive fluid needed for the polishing wheel 504a to the working area. The cooling or polishing fluid may extend the service life of the polishing wheel 504a, while addressing requirements for soft material removal. Alternatively, a dry polishing process may be adapted running no fluid to the polishing wheel 504a. The materials or particles removed from the edges of the substrate and the fluid are then collected by the dust collector 512.

As briefly discussed above, the polishing wheel 504a may be a wheel brush having a plurality of bristles. The bristles are generally set on the surface of a cylindrical motor core so that the bristles have a uniform length and distribution on the motor core. In various embodiments of the invention, the length of the bristles on the wheel brush after they have been set into the core may vary in a range of about 10 mm to about 200 mm. The bristles are set on the motor core to a density of about 10 bristles/cm² to about 2,000 bristles/cm², such as about 1,000 bristles/cm², depending upon application. The minimum or maximum diameter (i.e., the overall minimum or maximum cross-sectional dimension) of the brush may vary depending upon the size of the motor and space limited set by the processing assembly. In one aspect, the diameter of the polishing wheel 504a is ranging between about 1 inch and about 10 inches, such as about 2 inches. In another aspect, the diameter of the polishing wheel 504a is ranging between about 6 inches and 8 inches with ±0.01 mm brush tolerance. The width of the polishing wheel 504a may be adjusted to account for an edge deletion area, which is typically set by, for example, about 20 mm. In one aspect, the width of the polishing wheel 504a is ranging between about 0.2 inch and about 10 inches, such as 1.5 inches.

Generally, the bristle trim length and the bristle diameter (range can be about 2 mil to about 100 mil or about 0.001″ to about 0.1″) define the brush stiffness or hardness as will be explained below. There is a tradeoff between the number of bristles and the specific bristle diameter as far as the bristle density. One way to optimize the bristle density is to use crimped wires or flexible crimped bristles so the bristles are bent to support each other. The other way is to provide more bristles with the same bristle diameter which adds to the overall stiffness.

The material of the bristle for the polishing wheel 504a is specifically chosen taking into consideration the mechanical characteristics of the bristle. The bristles of the polishing wheel 504a may have poor bend recovery since there is very little relaxation time between substrates for bristle recovery from bending due to continuous flexing during cleaning. While a brush with higher bristle hardness or thicker bristles may provide better flexural strength and recovery, stiff bristles often scratch or damage the substrate and thus rendering the resulting product fail. To identify the suitable brush material for removing unwanted metal particles, various non-abrasive and medium abrasive brushes were tested and results are shown in Table 1 below.

TABLE 1

| Material | Particle removed? | Results |
|---|---|---|
| Soft cloth | No | Brush produces debris |
| Scotch-Brite ™ | Yes | Brush produces debris |
| Flexible bristle | No | Brush produces no debris |
| (Nylon 6-12, 0.006″) | | |
| Flexible bristle | No | Brush produces no debris |
| (Nylon 6-12, 0.010″) | | |
| Flexible bristle abrasive | Yes | Glass is scratched/ |
| (Nylon brush 120 grit) | | damaged by brush |
| Tampico flexible bristle | Yes | Glass is scratched/ |
| | | damaged by brush |

It can be seen from Table 1 that bristles made other than nylon brings debris or damage to the glass substrate. While flexible bristles made of Nylon 6-12 (where the first number indicates the number of carbon atoms connecting the two amine groups in the diamine and the second number indicates the number of carbon atoms connecting the two acid groups in the dibasic acid, including those in the acid groups) provides a better protection to the substrate, the observation of metal particles remained on the edges of the substrate suggests that an increased loading and/or a longer polishing time might be required for the best possible cleaning results using nylon bristles. In order to determine a suitable polishing time for particular Nylon bristle brushes, Nylon bristle brushes (Nylon 6-12 with a 0.006″ or 0.010″ diameter) were further tested with an upward loading of about 1lb/cm² pressed against edge surfaces of the substrate 302 at a conveyor speed of about 30 meter/min for different periods of time, as shown below in Table 2. In this example, the tested Nylon bristle brushes were rotated at about 3,000 RPM (Revolutions Per Minute).

TABLE 2

| Material | Polishing time (Sec) | Results | Loading applied? |
|---|---|---|---|
| Flexible bristle | 1 | Fair | Yes |
| Nylon bristle | 2 | Fair. Some | Yes |
| brush (Nylon | | residues still | |
| 6-12, 0.006″) | | remain | |
| | 5 | Good | Yes |
| | 10 | Good | Yes |
| Flexible bristle | 1 | Fair. Some | Yes |
| Nylon bristle | | residues still | |
| brush (Nylon | | remain | |
| 6-12, 0.010″) | 2 | Good | Yes |
| | 5 | Good | Yes |
| | 10 | Good | Yes |

It can be seen from Table 2 that a longer polishing time, such as about 2 seconds to about 10 seconds, is the best polishing period for edge cleaning of the substrate 302 using Nylon 6-12 bristles with a 0.006″ or 0.010″ diameter. The bristles of the polishing wheel 504a made of Nylon 6-12 may be preferred because it is non-abrasive and offers overall excellent tensile strength, wear resistance, high flexural strength, high modulus, and heat resistance. It has been proved that the polishing wheel 504a using Nylon 6-12 bristles demonstrates excellent polishing result as no metal oxidation was observed after exposure of the substrate 302 to powerful illumination at later laser edge delete stage. While Nylon 6-12 is tested and described as a preferred bristle material, other nylons that can be used for this purpose may include, but is not limited to, Nylon 4-6, Nylon 6, Nylon 6-6, Nylon 6-9, Nylon 6-10, Nylon 12, etc. Other plastic bristles such as bristles made of polypropylene, polyvinyl chloride, or animal bristles may also be used.

While Nylon 6-12 bristles with a 0.006″ or 0.010″ diameter are illustrated, it is contemplated that the bristles with various diameters may be adapted to provide a desired stiffness for cleaning. In one embodiment, the bristles may have a diameter ranging about 0.005″ to about 0.05″. While a single Nylon 6-12 bristle at a bristle diameter within this range and at trim length of about 0.75″ for example have a stiffness of about 8000 in/lb to about 0.8 in/lb, for example, a bundle of 100 closely stacked bristles with the same characteristics will have a stiffness of about 80 in/lb to about 0.008 in/lb, which have been shown to be able to provide the desired edge surface cleanliness without scratching the substrate. The calculation is done per the basic engineering equation for a round filament held at one end such as in a brush:

$$Stifness [ in \text{/} lb ] = \frac{{L}^{3}}{0.1473 \cdot E \cdot {d}^{4} \cdot N} ,$$

whereas L is the trim length in inches, E is the filament modules in p.s.i at 23° C. (73° F.) and 50% RH, d is the filament diameter in inches, and N is the number of filaments per tuft or bundle.

In cases where Nylon 6-12 bristles are used, the loading between the polishing wheel 504a and the substrate 302 may be adjusted by the constant pressure member 516 as discussed above to enhance the cleaning effectiveness. In one example, the polishing wheel 504a is provided with an upward loading of about 1lb/cm² to about 100 lb/cm². While not discussed here, it is contemplated that the conveyor speed, the motor speed (i.e., the number of revolutions of the brush) may also be adjusted in view of different types of brushes adapted or the material to be polished. The preference abrasive or non-abrasive depends mainly on the polishing type. For example, if the application requires polishing a substrate for better planarity or even cleaning with actual substrate material removal, then abrasive brush may be selected. When only cleaning is required without substrate polishing, then non-abrasive brush may be selected. RPM (revolutions per minute) for bristle brushes in each application can be designed independently considering the conveyor speed, the material adhesion to the substrate, and the bristle lifetime and stiffness. When non-abrasive brushes are used, a slower conveyor speed, for example about 10 m/min, is generally preferred and the number of revolutions of the brush may be selected from a range of about 300 rpm to about 8000 rpm. In contrast, when medium or abrasive brushes are used, the number of revolutions of the brush may be selected from a range of about 500 rpm to about 3000 rpm.

The concept of inventive edge cleaning module equipped with roller-type nylon brushes as described above advantageously allows for an improved metal particle removal from all four edges of the substrate prior to transferring to the edge delete tool in the automated solar cell fabrication line, thereby eliminating the chance of oxidizing metal particles which would cause color variation of the resulting solar cell module due to exposure of metal particles to powerful illumination used in the edge delete tool at later stage.

While the foregoing is directed to embodiments of the present invention, other and further embodiments of the invention may be devised without departing from the basic scope thereof, and the scope thereof is determined by the claims that follow.

What is claimed is:

1. A method for processing a solar cell device, comprising:
removing particles from edge regions of the solar cell device by a cleaning module with a constant loading applied onto a back surface of the solar cell device, wherein the cleaning module has two or more roller-type brushes disposed at opposed sides of a rotation table located before and/or after a quality assurance stage configured to measure and correct defects in the solar cell device; and
transferring the solar cell device into an edge deletion station in which an electromagnetic radiation energy is used to remove materials from a top surface of the solar cell device.

2. The method of claim 1, wherein the two or more roller-type brushes comprise bristles made of a material selected from the group consisting of Nylon 4-6, Nylon 6, Nylon 6-6, Nylon 6-9, Nylon 6-10, Nylon 12, and Nylon 6-12.

3. The apparatus of claim 1, wherein the two or more roller-type brushes comprises Nylon 6-12 bristles with a diameter ranging between about 0.005″ and about 0.05″ and a stiffness of about 0.8 in/lb to about 8000 in/lb.

4. A method for processing a solar cell device, comprising:
advancing the solar cell device onto a first rotation table equipped with a first set of edge cleaning brushes to remove particles from first two opposed edges of a solar cell device;
transferring the solar cell device into a quality assurance station configured to measure and correct defects in the solar cell device;
advancing the solar cell device onto a second rotation table equipped with a second set of edge cleaning brushes to remove particles from second two opposed edges of the solar cell device; and
transferring the solar cell device into an edge deletion station in which an electromagnetic radiation energy is used to remove materials from a top surface of the solar cell device.

5. The method of claim 4, wherein the first and second sets of edge cleaning brushes are configured to contact a back surface of the solar cell device with a constant upward loading.

6. The method of claim 4, wherein the first and second sets of edge cleaning brushes are disposed between two adjacent conveying rollers of the first and second rotation tables, respectively.

7. The method of claim 4, further comprising:
sensing the existence of the substrate to activate the first and second sets of edge cleaning brushes during cleaning.

8. The method of claim 4, wherein each of the first and second sets of edge cleaning brushes is equipped with two or more roller-type brushes disposed on opposing sides of the first and second rotation tables, respectively.

9. The method of claim 8, wherein the first and second sets of edge cleaning brushes are configured to rotate in a direction opposite to the direction of the solar cell device movement.

10. The method of claim 4, further comprising:
rotating the solar cell device by 90 degrees before transferring the solar cell device into the quality assurance station.

11. An apparatus for processing a solar cell device, comprising:
a quality assurance station configured to measure and correct defects in a solar cell device;
a conveyor configured to transport the solar cell device onto a first rotation table equipped with a first edge cleaning module, the first rotation table being located upstream the quality assurance station, and the first edge cleaning module comprising:
a first set of roller-type brushes disposed on opposed sides of the first rotation table, the first set of roller-type brushes being configured to be in contact with a back surface of the solar cell device with a constant upward loading; and
a motor configured to rotate the first set of roller-type brushes; and
an edge deletion station configured to remove material from a top surface of the solar cell device using an electromagnetic radiation energy.

12. The apparatus of claim 11, further comprising:
a second rotation table located downstream the quality assurance station and configured to receive the solar cell device on the conveyor from the quality assurance station, the second rotation table being equipped with a second edge cleaning module, the second edge cleaning module comprising:
a second set of roller-type brushes disposed on opposed sides of the second rotation table, the second set of roller-type brushes being configured in contact with a back surface of the solar cell device with a constant upward loading; and
a motor configured to couple and rotate the second set of roller-type brushes.

13. The apparatus of claim 12, further comprising:
one or more sensors configured to activate the first and second edge cleaning modules.

14. The apparatus of claim 12, wherein the first and second rotation tables are configured to rotate the solar cell device by 90 degrees.

15. The apparatus of claim 12, wherein the first and second sets of the roller-type brushes are disposed between two adjacent conveying rollers of the first and second rotation tables, respectively.

16. The apparatus of claim 12, wherein the first and second sets of the roller-type brushes comprise bristles made of a material selected from the group consisting of Nylon 4-6, Nylon 6, Nylon 6-6, Nylon 6-9, Nylon 6-10, Nylon 12, and Nylon 6-12.

17. The apparatus of claim 16, wherein the first and second sets of the roller-type brushes comprises Nylon 6-12 bristles having a diameter ranging from about 0.005″ to about 0.05″.

18. The apparatus of claim 17, wherein the first and second sets of the roller-type brushes are at trim length of about 0.75″ and have a stiffness of about 8000 in/lb to about 0.8 in/lb.

19. The apparatus of claim 12, wherein the first and second sets of the roller-type brushes provide the constant upward loading of about 1lb/cm² to about 100 lb/cm².

20. The apparatus of claim 12, wherein the motor is configured to rotate the pair of roller-type brushes in a range of about 300 rpm to about 8000 rpm.
